(19) United States
(12) Patent Application Publication
(10) Pub. No.: US 2008/0020569 A1
(43) Pub. Date: Jan. 24, 2008

(54) Method for Manufacturing Semiconductor Device

(76) Inventor: Eun Soo Jeong, Eumseong-gun (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/779,718

(22) Filed: Jul. 18, 2007

(30) Foreign Application Priority Data
Jul. 18, 2006 (KR) 10-2006-0066835

(51) Int. Cl. H01L 21/441

(52) U.S. Cl. 438/670; 257/E21.477

(57) ABSTRACT

Provided is a method for manufacturing a semiconductor device. In the method, photoresist patterns having a first width are formed on a semiconductor substrate, and the semiconductor substrate is etched using the photoresist patterns as a mask to form a semiconductor protrusion portion. An oxide layer is formed on an entire surface of the semiconductor substrate including the semiconductor protrusion portion. Subsequently, the semiconductor protrusion portion is removed to form a trench surrounded by the oxide layer. After that, blanket-etching is performed on the trench to leave only a portion of the oxide layer formed around the trench. Metal is deposited on an entire surface of the semiconductor substrate including the oxide layer, and the oxide layer is removed to form a metal line.

### CROSS-REFERENCE TO RELATED APPLICATION

The present application claims the benefit under 35 U.S.C. §119 of Korean Patent Application No. 10-2006-0066835, filed Jul. 18, 2006, which is hereby incorporated by reference in its entirety.

### BACKGROUND

As semiconductor devices become highly integrated, miniaturization of devices is under progress. Miniaturizing a semiconductor device also requires miniaturization/reduction of line size. However, a photolithography process performed through a related art light source such as ArF, KrF, and F₂ light sources, and patterning of a photoresist has a limitation in realizing a fine pattern of a metal line.

That is, there is a limitation in realizing a line of several nanometers due to limitations of an optical system and limitation of resolution of a photoresist polymer itself.

### BRIEF SUMMARY

Embodiments of the present invention provide a method for manufacturing a semiconductor device that can precisely control a line width of a metal line through an oxidation process.

In one embodiment, a method for manufacturing a semiconductor device comprises: forming photoresist patterns having a first width on a semiconductor substrate; etching the semiconductor substrate using the photoresist patterns as a mask to form a semiconductor protrusion portion; forming an oxide layer on an entire surface of the semiconductor substrate including the semiconductor protrusion portion; removing the semiconductor protrusion portion to form a trench surrounded by the oxide layer; performing blanket-etching on the trench to leave only a portion of the oxide layer formed about the trench; depositing metal on the entire surface of the semiconductor substrate including the oxide layer; and removing the oxide layer to form a metal line.

The details of one or more embodiments are set forth in the accompanying drawings and the description below. Other features will be apparent from the description and drawings, and from the claims.

### BRIEF DESCRIPTION OF THE DRAWINGS

FIGS. 1-9 are cross-sectional views for illustrating a method for manufacturing a semiconductor device according to an embodiment of the present invention.

FIG. 1 is a cross-sectional view after a photoresist has been coated according to an embodiment.

FIG. 2 is a cross-sectional view after photoresist patterns have been formed according to an embodiment.

FIG. 3 is a cross-sectional view after a semiconductor protrusion portion has been formed according to an embodiment.

FIG. 4 is a cross-sectional view after an oxide layer has been formed according to an embodiment.

FIG. 5 is a cross-sectional view after an oxide layer has been planarized according to an embodiment.

FIG. 6 is a cross-sectional view after a semiconductor protrusion portion has been removed according to an embodiment.

FIG. 7 is a cross-sectional view after an oxide layer has been blanket-etched according to an embodiment.

FIG. 8 is a cross-sectional view after metal has been deposited according to an embodiment.

FIG. 9 is a side cross-sectional view of a device shape after a metal pattern has been formed in a method for manufacturing a semiconductor device according to an embodiment.

### DETAILED DESCRIPTION

A method for manufacturing a semiconductor device according to embodiments of the present invention will be described with reference to the accompanying drawings.

In the description of embodiments, it will be understood that when a layer (or film) is referred to as being ‘on’ another layer or substrate, it can be directly on the another layer or substrate, or intervening layers may also be present. Accordingly, when a layer is referred to as being “directly on” another layer or substrate, no intervening layer is present.

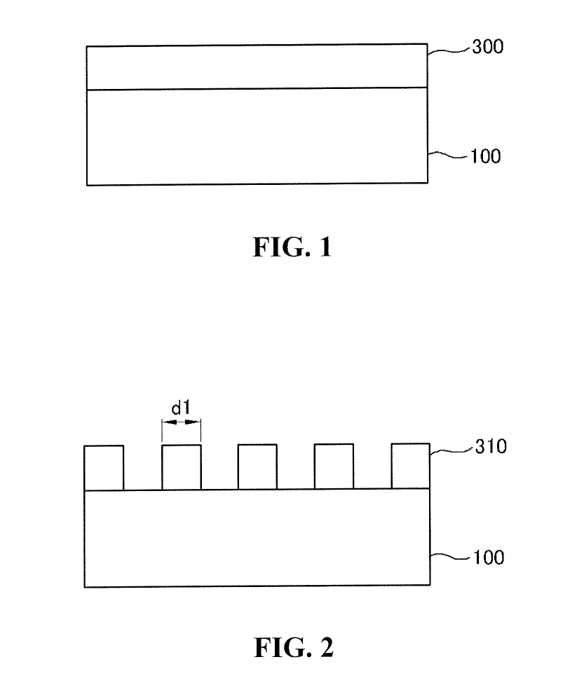

Referring to FIG. 1, a photoresist 300 can be coated on a semiconductor substrate 100 formed of, for example, amorphous silicon.

Referring to FIG. 2, photoresist patterns 310 having a first width d1 can be formed by exposure and developing processes of the photoresist 300. At this point, the first width d1 can be a minimum line width that can be realized through a photolithography process, and can be determined with consideration of the width of a line to be finally formed.

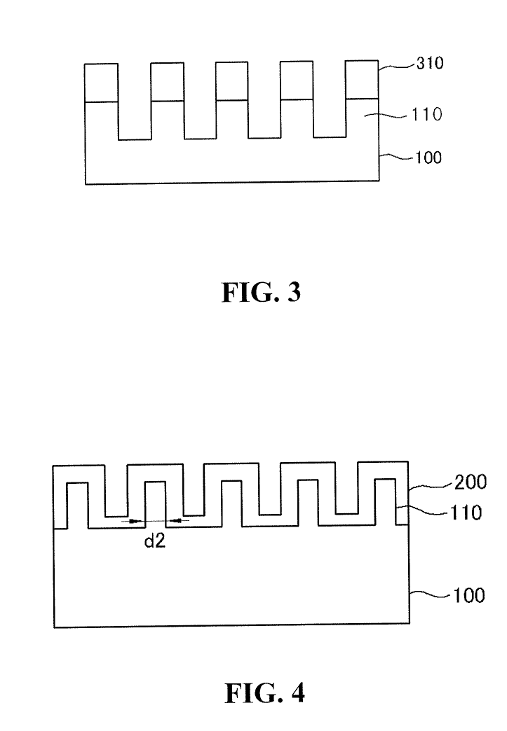

Referring to FIG. 3, after the photoresist patterns 310 having the first line width d1 are formed, the semiconductor substrate 100 can be etched using the photoresist patterns 310 as a mask.

Accordingly, a the semiconductor protrusion portion 110 is formed as illustrated in FIG. 3. The semiconductor protrusion portion 110 has a ridge shape and has the first width d1 as that of the photoresist patterns 310.

Next, referring to FIG. 4, after the photoresist patterns 310 are removed, an oxide layer 200 can be formed on an entire surface of the semiconductor substrate 100 including the semiconductor protrusion portion 110.

The oxide layer 200 can be formed by performing a wet oxidation on the semiconductor substrate 100. In one embodiment, the wet oxidation is performed by injecting vapor (H₂O) for a short time at high temperature of about 900-1100° C.

Here, 40-50% of the oxide layer 200 formed through the wet oxidation is formed inside the semiconductor substrate 100, and the rest of the oxide layer 200 is formed on the outside of the semiconductor substrate 100. That is, oxidation of the amorphous silicon of the substrate 100 occurs such that as the oxide layer forms on the substrate, a portion of the substrate becomes part of the oxide layer 200.

Therefore, the semiconductor protrusion portion 110 becomes a second width d2 narrower than the first width d1 through the generation of the oxide layer 200.

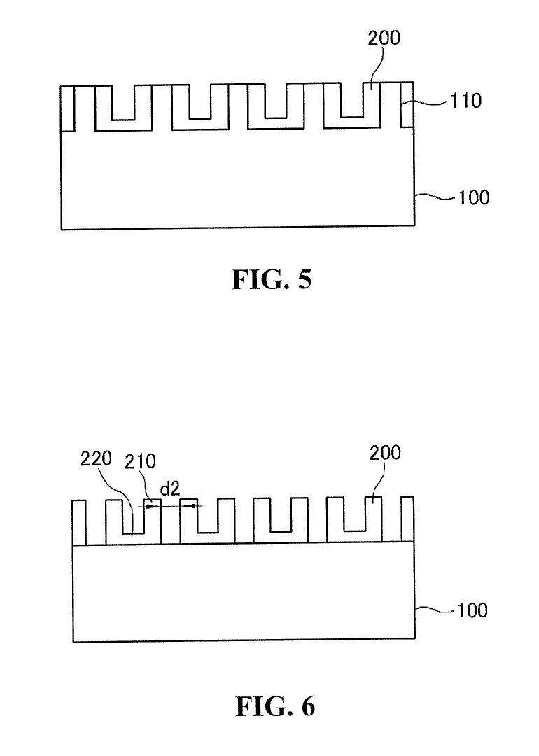

Referring to FIG. 5, after forming the oxide layer 200, the oxide layer 200 is planarized until the upper surface of the semiconductor protrusion portion 110 having the second width d2 is exposed. In an embodiment, the oxide layer 200 can be polished through a chemical mechanical polishing (CMP) process.

Referring to FIG. 6, the semiconductor protrusion portion 110 having the second width d2 exposed by the planarization of the oxide layer 200 can then be removed. Therefore, a trench surrounded by the oxide layer 200 is formed. The trench can be formed by selectively wet-etching only the semiconductor protrusion portion 110 formed of silicon using fluorinated ethylene propylene (FEP).

That is, a first portion 210 of the oxide layer 200 grown from the lateral sides of the semiconductor protrusion portion 110, and a second portion 220 of the oxide layer 200 grown from the upper surface of the substrate 100 remain.

Subsequently, the oxide layer 200 where the first portion 210 and the second portion 220 remain is blanket-etched. The etching process can be reactive ion etching (RIE), and is performed until the second portion 220 of the oxide layer 200 is completely removed.

Since the RIE is performed in a vertical direction, the width of the first portion 210 does not reduce, and the first and the second portions 210 and 220 are etched in only a height direction.

That is, the first portion 210 of the oxide layer 200 is etched by the height of the second portion 220.

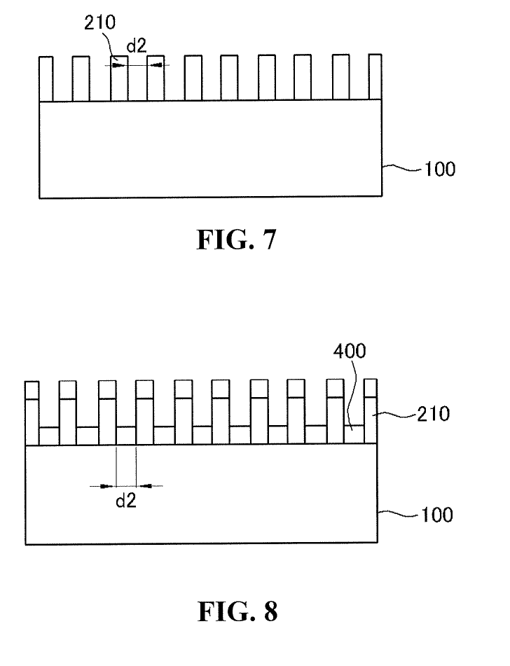

Therefore, referring to FIG. 7, the first portion 210 of the oxide layer 200 that remains after the etching is separated by the second width d2 from an adjacent first portion 210 of the oxide layer 200. The semiconductor substrate 100 is exposed through the space between the first regions 210 separated from each other.

Next, referring to FIG. 8, metal 400 can be deposited on the entire surface of the substrate 100. The metal 400 can include copper. In one embodiment, the deposition of the metal 400 can be performed using electron (E)-beam evaporating. Therefore, the metal 400 fills the trench surrounded by the first portions 210, and is deposited on the first portions 210.

In an embodiment, after the metal 400 is deposited, the first portions 210 of the oxide layer 200 can be removed through an etching solution.

At this point, the first portions 210 of the oxide layer 200 can be removed using a lift-off operation. The portion of the metal 400 remaining on the first portions 210 is removed together with the oxide, and a portion of the metal 400 between the first portions remains.

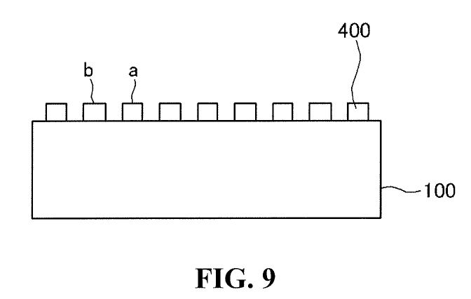

Therefore, as illustrated in FIG. 9, a first metal line ‘a’ and a second metal line ‘b’ are alternately formed.

At this point, the first and second metal lines ‘a’ and ‘b’ can have different widths, depending on the separation distance of the photoresist patterns 310 having the first width d1.

For example, assuming that the separated distance between adjacent photoresist patterns 310 is d3, the thickness of the oxide layer 200 can be given as x, the thickness of the oxide layer 200 formed on the semiconductor substrate 100 and inside the semiconductor protrusion portion 110 is x1, and the thickness of the oxide layer 200 formed outside of the semiconductor protrusion portion 110 is x2, where x=x1+x2. [0040] In addition, assuming that the width of the first metal line ‘a’ is d2, which is the second width as illustrated in FIG. 8, and the width of the second metal line ‘b’ is d4, then the widths of the metal lines can be given by d2=d1−2(x1) and d4=d3−2(x2). At this point, since x1 and x2 are factors determined by experiments, the widths of the first metal line ‘a’ and the second metal line ‘b’ can be set to be equal to or different from each other by controlling the widths d1 and d3.

As described above, according to an embodiment, a semiconductor device can be miniaturized by forming the line of the semiconductor device smaller than the width between photoresist patterns defining a semiconductor protrusion portion.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device, the method comprising:
forming photoresist patterns having a first width on a semiconductor substrate;
etching the semiconductor substrate using the photoresist patterns as a mask to form a semiconductor protrusion portion;
forming an oxide layer on an entire surface of the semiconductor substrate including the semiconductor protrusion portion;
removing the semiconductor protrusion portion to form a trench surrounded by the oxide layer;
performing blanket-etching on the trench to leave only a portion of the oxide layer formed around the trench;
depositing metal on the entire surface of the semiconductor substrate including the portion of the oxide layer; and
removing the portion of the oxide layer to form a metal pattern.

2. The method according to claim 1, further comprising removing the photoresist patterns after etching the semiconductor substrate using the photoresist patterns as a mask.

3. The method according to claim 1, wherein removing the semiconductor protrusion portion to form the trench comprises:
polishing the oxide layer to expose the semiconductor protrusion portion; and
etching the exposed semiconductor protrusion portion to remove the semiconductor protrusion portion.

4. The method according to claim 3, wherein etching the exposed semiconductor protrusion portion comprises selectively wet-etching the semiconductor protrusion portion using fluorinated ethylene propylene.

5. The method according to claim 1, wherein forming the oxide layer comprises wet-oxidizing a surface of the semiconductor substrate to form the oxide layer.

6. The method according to claim 5, wherein the wet oxidation is performed at a temperature of 900-1000° C.

7. The method according to claim 1, wherein forming the oxide layer causes the semiconductor protrusion portion to have a second width narrower than the first width.

8. The method according to claim 7, wherein 40-50% of a thickness of the oxide layer is formed from the semiconductor protrusion portion.

9. The method according to claim 1, wherein performing blanket etching comprises performing a reactive ion etching process, wherein the oxide layer is removed in only a height direction through the reactive ion etching process.

10. The method according to claim 1, wherein depositing metal comprises depositing copper using an electron beam evaporating process.

11. The method according to claim 1, wherein a thickness of the oxide layer, x, is given by the equation x=x1+x2, and a thickness of the semiconductor protrusion portion d2 after forming the oxide layer is given by the equation d2=d1−2(x1),
where d1 is the first width, x1 is a thickness of a portion of the oxide layer formed from the semiconductor protrusion portion, and x2 is a thickness of a portion of the oxide layer formed outside of the semiconductor protrusion portion, and
wherein the metal pattern comprises a first metal line having a width of d1, and a second metal line having a width of d3−2(x2),
where d3 is a distance between the photoresist patterns.
